(19) United States
(12) Patent Application Publication
(10) Pub. No.: US 2024/0429156 A1
(43) Pub. Date: Dec. 26, 2024

(54) Embedding Metal-Insulator-Metal Structure In Silicon Oxide In A Copper Redistribution Layer Scheme

(71) Applicant: Taiwan Semiconductor Manufacturing Company, Ltd., Hsin-Chu (TW)

(72) Inventors: Chia-Yueh Chou, Taoyuan City (TW); Hsiang-Ku Shen, Hsinchu City (TW); Li-Chung Yu, Kaohsiung City (TW); Wen-Ling Chang, Miaoli County (TW); Chen-Chiu Huang, Taichung City (TW); Dian-Hau Chen, Hsinchu (TW); Cheng-Hao Hou, Hsinchu City (TW); Shin-Hung Tsai, Hsinchu City (TW); Alvin Universe Tang, Hsinchu City (TW); Kun-Yu Lee, Tainan City (TW); Chun-Hsiu Chiang, Taipei City (TW)

(21) Appl. No.: 18/337,963

(22) Filed: Jun. 20, 2023

(51) Int. Cl. H01L 23/522; H01L 21/768; H01L 23/528

(52) U.S. Cl. CPC H01L 23/5223; H01L 21/76832; H01L 21/76877; H01L 23/5226; H01L 23/528; H01L 21/7684; H01L 21/76843

(57) ABSTRACT

A device includes a first dielectric layer. A second dielectric layer is disposed over the first dielectric layer. The second dielectric layer and the first dielectric layer have different material compositions. A metal-insulator-metal (MIM) structure is embedded in the second dielectric layer. A third dielectric layer is disposed over the second dielectric layer. The third dielectric layer and the second dielectric layer have different material compositions. The first dielectric layer or the third dielectric layer may contain silicon nitride (SiN), the second dielectric layer may contain silicon oxide (SiO₂).

### BACKGROUND

The semiconductor integrated circuitry (IC) industry has experienced rapid growth. Technological advances in IC design and material have produced generations of ICs where each generation has smaller and more complex circuits than previous generations. During the course of IC evolution, functional density (i.e., the number of interconnected devices per unit chip area) has generally increased while geometry size (i.e., the smallest component (or line) that can be created using a fabrication process) has decreased.

As the semiconductor device scaling down continues, challenges in fabrication may arise. For example, a metal-insulator-metal (MIM) structure may be used to implement microelectronic components, such as capacitors. The MIM structure may be formed as a part of a copper redistribution layer (RDL) scheme. However, existing processes for implementing the copper RDL scheme may lead to subpar characteristics of the insulator layers in the MIM structure, such as poor crystallinity and/or lower-than-desired dielectric constant. As a result, the performance of the MIM structure may be degraded.

Therefore, although existing semiconductor fabrication methods have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1-16 are sectional side views of an integrated circuitry (IC) device (or portions thereof) at various fabrication stages constructed according to various aspects of the present disclosure.

FIG. 17 is a flowchart of a method to fabricate an IC device in accordance with an embodiment of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

Integrated Circuitry (IC) chips contain a plurality of different types of microelectronic components, such as transistors, resistors, inductors, capacitors, etc. For each of these types of microelectronic components, there may be a variety of methods of fabrication, resulting in different structures thereof. In some cases, capacitors may be implemented using a metal-insulator-metal (MIM) structure, in either a copper (Cu) redistribution layer (RDL) scheme or an aluminum copper (AlCu) RDL scheme. The MIM structure may include a plurality of metal-containing layers and a plurality of insulator layers, where each of the insulator layers is located between two respective metal-containing layers. In an existing copper RDL scheme, the MIM structure is embedded in a nitride-based material. For example, the layer directly above the MIM structure and the layer directly below the MIM structure in existing RDL schemes may both be silicon nitride. Unfortunately, silicon nitride does not promote good formation of a metal-containing layer (of the MIM structure) thereover. The situation is exacerbated when an insulator layer (of the same MIM structure) has to be formed over the poorly formed metal-containing layer, which could lead to poor crystalline quality of the insulator layer. In turn, the insulator layer may not be able to achieve a desired dielectric constant, and/or the MIM structure could experience failures such as time-dependent dielectric breakdown (TDDB). Consequently, IC device performance and/or yield may be degraded.

The present application pertains to an improved copper RDL scheme, in which a MIM structure is embedded in an oxide-based material, for example, in a silicon oxide (SiO₂) material. The metal-containing layer of the MIM is formed directly on the oxide-based material, which promotes good formation of the metal-containing layer. The insulator layer that is subsequently formed over the metal-containing layer may also have a better crystal lattice structure in the present application (compared to existing copper based RDL schemes). As a result, the insulator layer may achieve a desired high dielectric constant, and failures such as TDDB may be reduced.

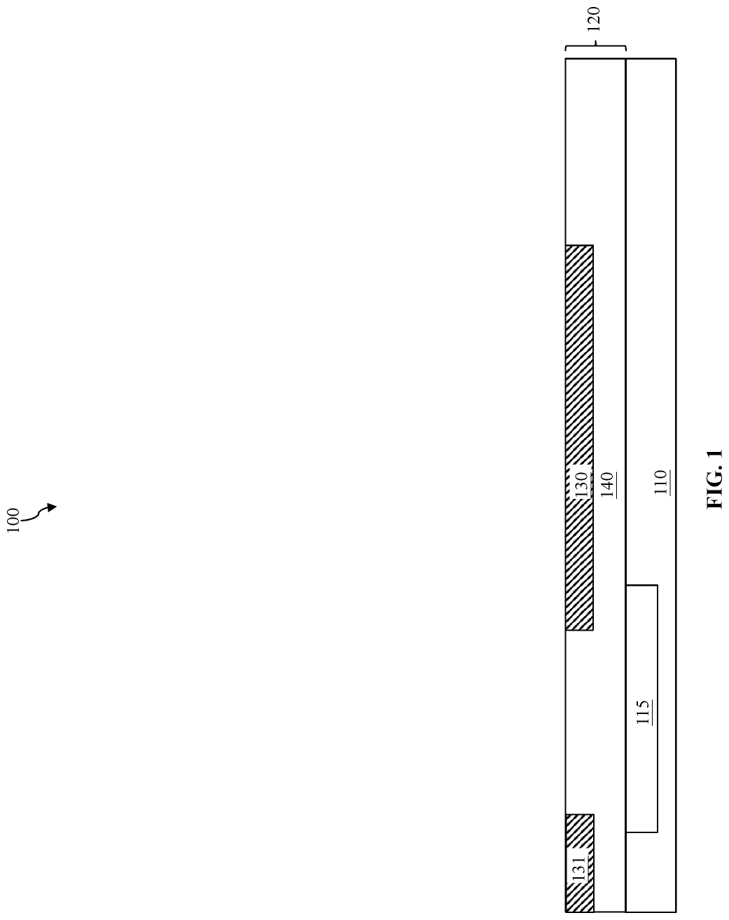

The process flow for implementing the copper RDL of the present disclosure is now discussed below with reference to FIGS. 1-15, which are diagrammatic fragmentary cross-sectional side view drawings of an IC structure 100 (or a work piece) constructed according to various aspects of the present disclosure in one embodiment.

Referring now to FIG. 1, the IC structure 100 includes an IC substrate 110. In some embodiments, the IC substrate 110 includes a semiconductor substrate, such as a silicon substrate. The IC substrate 110 may also include various devices, such as field-effect transistors (FETs), memory cells, imaging sensors, passive devices, other devices, or combinations thereof. In some embodiments, the IC substrate 110 includes flat active regions with various IC devices, such as plain field-effect transistors (FETs). In some other embodiments, the IC substrate 110 includes fin (e.g., vertically protruding) active regions with various IC devices formed thereon. It is understood that the fin active regions may also be used to form gate-all-around (GAA) devices in some embodiments. In any case, as a simplified non-limiting example herein, electrical circuitry 115 is shown as being formed in the IC substrate 110 in FIG. 1. The electrical circuitry 115 may include planar type transistors or FinFET type (or GAA type) transistors.

The IC structure 100 also includes an interconnection structure 120 formed over the semiconductor substrate. The interconnection structure 120 includes various conductive components, such as metal lines (e.g., metal line 130 or metal line 131), contacts, and vias, to provide horizontal and vertical electrical routing. The metal lines such as the metal line 130 are distributed in multiple levels of metal layers, such as a first metal layer (e.g., a M1 layer), a second metal layer (e.g., a M2 layer), . . . and a top metal layer. In some embodiments, the metal lines 130-131 belong to a topmost metal layer of the interconnect structure 120, and the metal lines and/or vias of the other metal layers of the interconnect structure 120 are not specifically illustrated herein for reasons of simplicity.

Among other things, the conductive components of the interconnection structure 120 may provide electrical connectivity to the electrical circuitry 115. The interconnection structure 120 also includes a dielectric material 140 to provide electrical isolation among the various conductive components, so as to prevent electrical shorting. In some embodiments, the dielectric material 140 may include an oxide material, such as silicon oxide. It may be said that the metal lines such as metal lines 130-131 are embedded in the dielectric material 140.

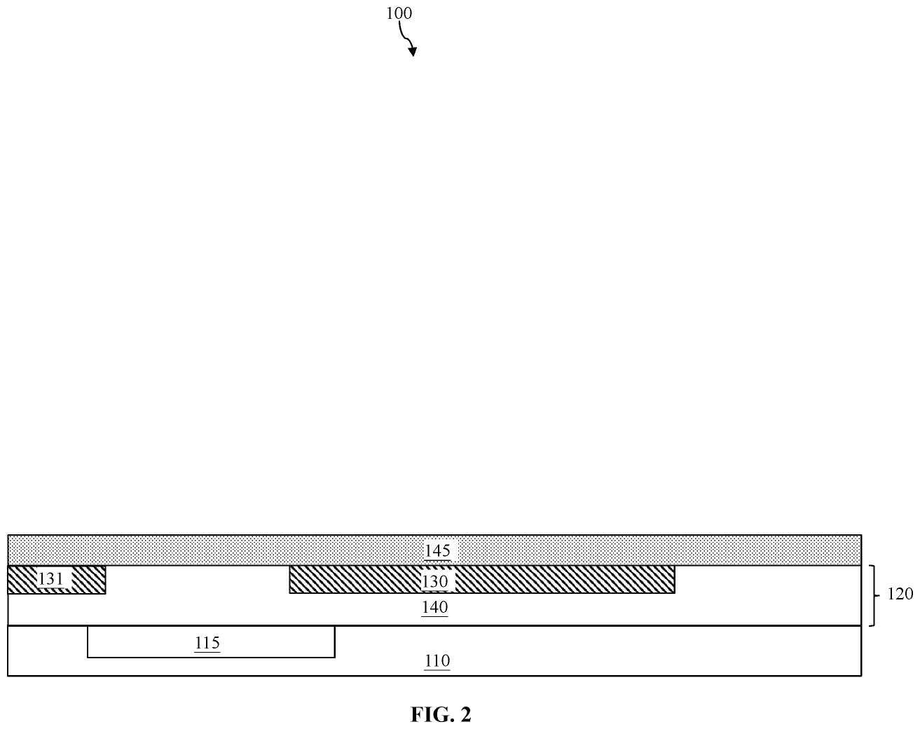

Referring now to FIG. 2, a planarization process, such as a chemical mechanical polishing (CMP) process, may be performed to planarize an upper surface of the interconnect structure 120. Thereafter, a dielectric layer 145 may be formed over the planarized upper surface of the interconnect structure 120, including over the metal lines 130 and 131. In some embodiments, the dielectric layer 145 may be formed using one or more deposition processes, such as chemical vapor deposition (CVD), physical vapor deposition (PVD), atomic layer deposition (ALD), or combinations thereof. In some embodiments, the dielectric layer 145 is formed to have a silicon carbon nitride (SiCN) material composition. In other embodiments, the dielectric layer 145 may have a silicon nitride (SiN) material composition.

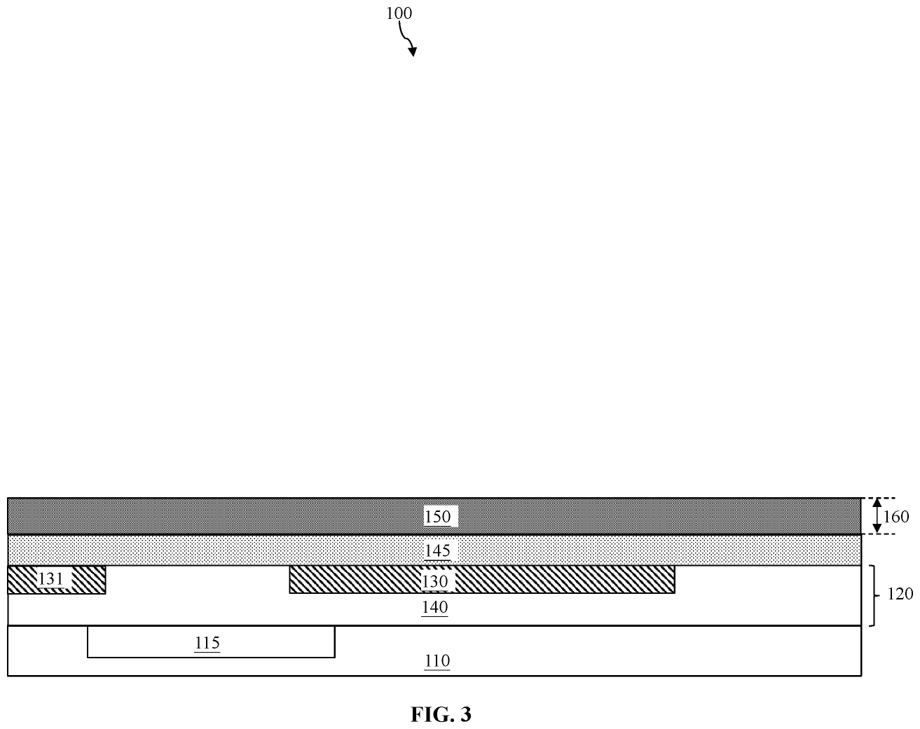

Referring now to FIG. 3, a dielectric layer 150 is formed over the dielectric layer 145. The dielectric layer 150 may be formed using CVD, PVD, ALD, a high density plasma chemical vapor deposition (HDPCVD), or combinations thereof. In some embodiments, the material composition of the dielectric layer 150 is configured to protect other layers of the IC structure 100 below from contaminant particles and/or other elements such as undesired moisture, etc. In this manner, the dielectric layer 150 may serve as a passivation film and may be interchangeably referred to as such. In some embodiments, the dielectric layer 150 includes a silicon nitride (SiN) film. The dielectric layer 150 is also formed to have a thickness 160. In some embodiments, the thickness 160 is in a range between about 200 nanometers (nm) and about 1000 nm.

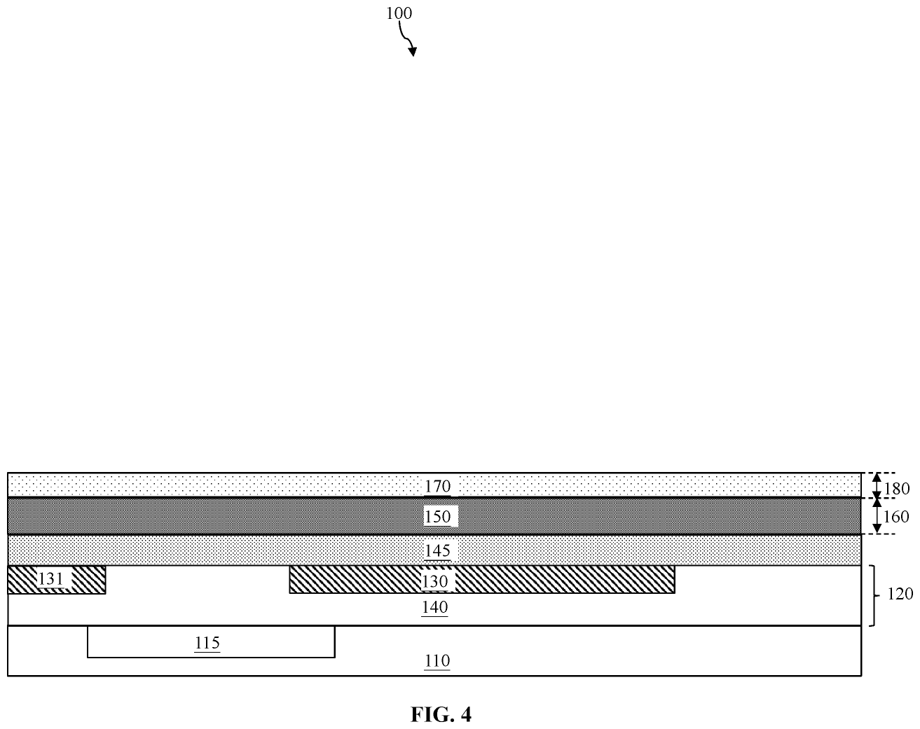

Referring now to FIG. 4, a dielectric layer 170 is formed over the dielectric layer 150. The dielectric layer 170 may be formed using CVD, PVD, ALD, HDPCVD, or combinations thereof. The material composition of the dielectric layer 170 is configured to facilitate the formation of a metal-containing layer of a MIM structure (to be formed over the dielectric layer 170). In some embodiments, the material composition of the dielectric layer 170 is configured to include an oxide material. For example, the dielectric layer 170 may be configured to have a silicon oxide (SiO₂) material composition. Silicon oxide will provide a good surface for a metal-containing layer (e.g., titanium nitride) to be formed thereon. As such, the dielectric layer 170—which is not implemented in existing copper RDL schemes-will facilitate the formation of a higher quality metal-containing layer of the MIM structure. The dielectric layer 170 is also formed to have a thickness 180. In some embodiments, the thickness 180 is in a range between about 50 nm and about 500 nm. In some embodiments, a ratio of the thickness 180 and the thickness 160 is in a range between about 0.1 and about 0.5.

It is understood that the above ranges of the thicknesses and the ratios are not randomly chosen but specifically configured. For example, if the thickness 180 is too low compared to the thickness 160 (i.e., the ratio of the thickness 180 and the thickness 160 is too small), then the dielectric layer 170 may not be sufficiently thick to serve as a good base layer on which to form the metal-containing layer of the MIM structure. In other words, the amount of improvement in quality of the metal-containing layer and the insulator layer of the MIM structure may be minimal. On the other hand, if the thickness 180 is too high compared to the thickness 160 (i.e., the ratio of the thickness 180 and the thickness 160 is too high), then the dielectric layer 150 may not be sufficiently thick to serve as a passivation structure. Here, by configuring the thicknesses 160 and 180 carefully, the dielectric layers 150 and 170 are optimized, in that the dielectric layer 150 can adequately serve as a passivation structure, while the dielectric layer 170 can serve as a good base material on which to form the metal-containing layer of the MIM structure.

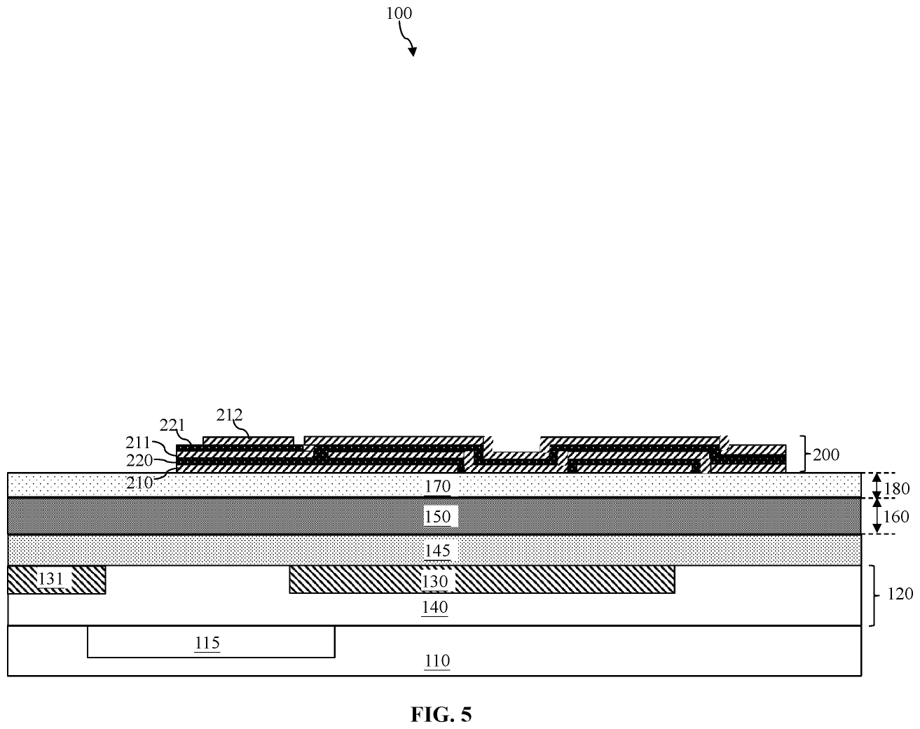

Referring now to FIG. 5, a MIM structure 200 is formed over the dielectric layer 170. The MIM structure 200 includes a plurality of metal-containing layers, such as metal-containing layers 210-212, as well as a plurality of insulator layers, such as insulator layers 220-221. In some embodiments, the metal-containing layers each include titanium nitride (TiN), titanium aluminum (TiAl), or copper (Cu), while the insulator layers each include a high-k dielectric material. In some embodiments, a high-k dielectric material may be a dielectric material with a dielectric constant greater than about 4 (e.g., greater than a dielectric constant of silicon oxide). Suitable candidates for the high-k dielectric materials include, but are not limited to: hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, the like, or combinations thereof. In the illustrated embodiment, the insulator layers 220-221 each include hafnium zirconium oxide (HZO).

The metal-containing layers and the insulator layers may each be formed by a plurality of deposition and patterning processes. For example, the metal-containing layer 210 may be formed by first depositing a layer of metal-containing material (e.g., TiN) over the upper surface of the dielectric layer 170, and subsequently patterning the deposited layer of metal-containing material using a lithography process. As a part of the lithography process, a patterned photoresist layer may be formed over the deposited layer of metal-containing material. Using the patterned photoresist layer as a mask, the deposited layer of metal-containing material may be etched. Portions of the deposited layer of metal-containing material not protected by the patterned photoresist layer are etched away, while portions of the deposited layer of metal-containing material located underneath the patterned photoresist layer are protected and may remain after the etching process is performed. The remaining portions of the deposited layer of metal-containing material forms the metal-containing layer 210. The rest of the metal-containing layers 211-212 may be formed using similar processes as those used to form the metal-containing layer 210. It is understood that each of the metal-containing layers 210-212 may serve as an electrode or a conductive plate of a capacitor of the MIM structure.

The insulator layers 220-221 may also be formed by a plurality of deposition processes (e.g., deposition processes to deposit the high-k dielectric material, such as HZO, over the respective metal-containing layers) and patterning processes. Note that each of the insulator layers 220-221 is disposed between two respective metal-containing layers. For example, the insulator layer 220 is disposed between the metal-containing layer 210 (which is located below the insulator layer 220) and the metal-containing layer 211 (which is located above the insulator layer 220). Meanwhile, the insulator layer 221 is disposed between the metal-containing layer 211 (which is located below the insulator layer 221) and the metal-containing layer 212 (which is located above the insulator layer 221). It is understood that the insulator layers 220-221 provide electrical isolation between the metal-containing layers 210-212. They also serve as the dielectric material that is sandwiched between the conductive plates/electrodes of the capacitor of the MIM structure 200.

As discussed above, existing copper RDL schemes form a bottommost one of metal-containing layer directly on an uppermost surface of a silicon nitride material. However, silicon nitride is not an ideal material for a high quality metal-containing layer to be formed directly thereon. For example, titanium nitride (as an example metal-containing layer) that is directly deposited on silicon nitride may exhibit a low amount of (111) plane in a Miller index. When an insulator layer is subsequently formed on the titanium nitride (or another suitable metal-containing layer material) with such a low amount of (111) plane, the resulting insulator layer may suffer from problems such as a low crystallinity and/or a low dielectric constant. In turn, the resulting MIM structure formed using existing copper RDL processes may suffer from reliability issues and/or defects such as time dependent dielectric breakdown (TDDB), which is when a dielectric material breaks down over time as a result of an application of a relatively low electric field. When TDDB occurs, the insulator layer may act more as a conductive layer, as electrical current may tunnel through the insulator layer. This may render the capacitor of the MIM structure non-functional, or at least function sub-optimally to the extent that it functions at all.

In comparison, the copper RDL process of the present disclosure forms the MIM structure 200 over an oxide-based material (e.g., silicon oxide), rather than over silicon nitride. For example, the metal-containing layer 210 (i.e., the bottommost one of the metal-containing layers) is deposited directly on an upper surface of the dielectric layer 170, which has a silicon oxide material composition. In embodiments where the metal-containing layer 210 has a titanium nitride material composition, the titanium nitride material of the metal-containing layer 210 (deposited directly on silicon oxide) may have a higher amount of (111) plane in the Miller index compared to titanium nitride material formed directly on silicon nitride. The insulator layer 220—which has a hafnium zirconium oxide material composition in this embodiment-is deposited directly on the titanium nitride material of the metal-containing layer 210 with the high amount of (111) plane. Hafnium zirconium oxide may have a favorable plane of (111) because it has low surface energy and stability against an epitaxial strain. As such, the hafnium zirconium oxide of the insulator layer 220 may have better/higher crystallinity and/or a greater dielectric constant. In turn, the resulting MIM structure 200 formed using the copper RDL process of the present disclosure is less likely to suffer from reliability issues and/or defects such TDDB, and therefore device performance, yield, and/or reliability may be improved.

Note that the capacitor of the MIM structure 200 is a multi-plate capacitor that may include more than just two conductive plates (or more than two metal-containing layers). For example, the capacitor of the MIM structure 200 as shown in FIG. 5 may include three conductive plates (corresponding to the metal-containing layers 210-212) that are vertically stacked over one another. Since a capacitor includes two electrodes, some of these conductive plates may be electrically coupled together to serve as one electrode. For example, in some embodiments, one segment of the metal-containing layer 211 may serve as one electrode of the capacitor of the MIM structure 200, and a segment of the metal-containing layer 210 may be electrically coupled to a segment of the metal-containing layer 212 to collectively serve as another electrode of the capacitor of the MIM structure 200.

It is understood that FIG. 5 merely illustrates a non-limiting example of the MIM structure 200. The arrangement or configuration of the various layers of the MIM structure shown in FIG. 5 is not meant to be limiting. The MIM structure 200 may have other shapes or configurations, or other number of metal-containing layers (e.g., more than three) or insulator layers in other embodiments.

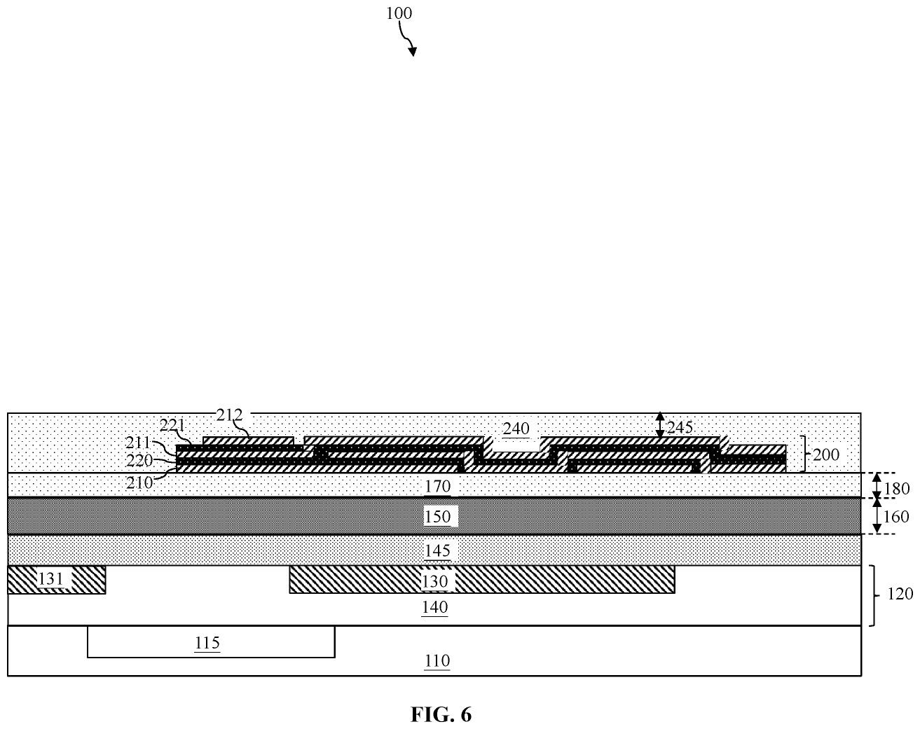

Referring now to FIG. 6, a dielectric layer 240 is formed over the MIM structure 200 and over the dielectric layer 170. In the cross-sectional side view of FIG. 6, the dielectric layer 170 and the dielectric layer 240 collectively embed the MIM structure 200 therein. The dielectric layer 240 may be formed by a suitable deposition process such as CVD, PVD, ALD, or HDPCVD. In some embodiments, the material composition of the dielectric layer 240 is configured to be the same as the material composition of the dielectric layer 170. For example, in embodiments where the dielectric layer 170 has a silicon oxide material composition, the dielectric layer 240 has a silicon oxide material composition as well. Note that there may or may not be an interface between the dielectric layer 170 and the dielectric layer 240 in some embodiments.

As shown in FIG. 6, a portion of the dielectric layer 240 disposed directly over an uppermost surface of the MIM structure 200 has a thickness 245. In other words, the thickness 245 corresponds to a distance that separates the uppermost surface of an uppermost one of the metal-containing layers (which is the metal-containing layer 212 in the embodiment shown in FIG. 6) and the uppermost surface of the dielectric layer 240. In some embodiments, the thickness 245 is similar in value to the thickness 180. For example, the thickness 245 and the thickness 180 may vary within less than 20% of one another in value.

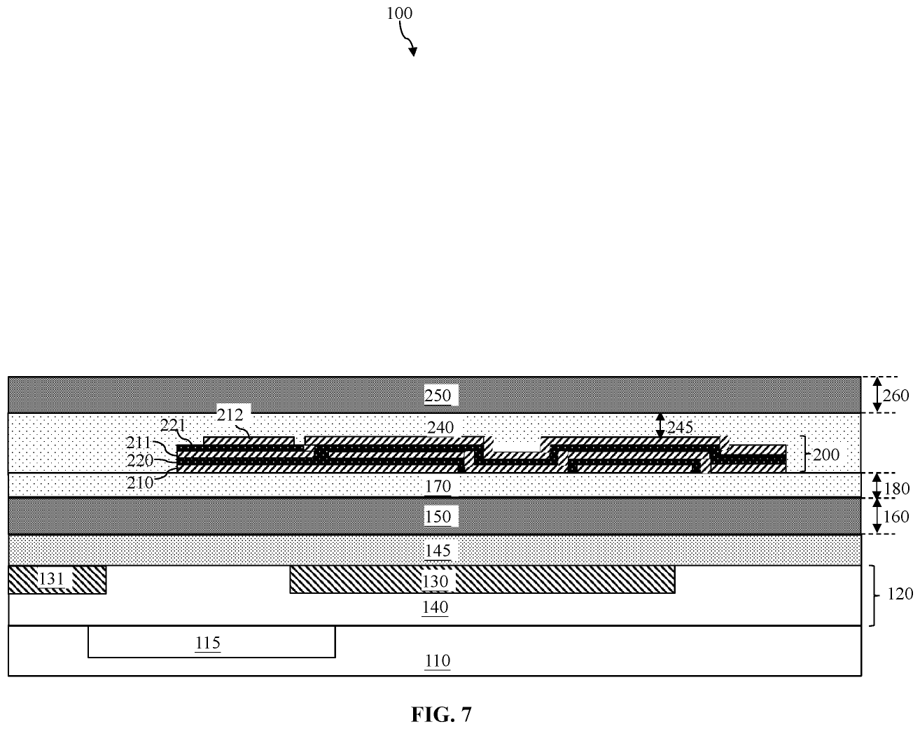

Referring now to FIG. 7, a dielectric layer 250 is formed over the dielectric layer 240. The dielectric layer 250 may be formed using CVD, PVD, ALD, HDPCVD, or combinations thereof. In some embodiments, the material composition of the dielectric layer 250 is configured to protect other layers of the IC structure 100 below from contaminant particles and/or other elements such as undesired moisture, etc. In this manner, the dielectric layer 250—similar to the dielectric layer 150—may serve as a passivation film and may be interchangeably referred to as such. In some embodiments, the dielectric layer 250 includes a silicon nitride (SiN) film. The dielectric layer 250 is also formed to have a thickness 260. In some embodiments, the thickness 260 is in a range between about 200 nm and about 1000 nm.

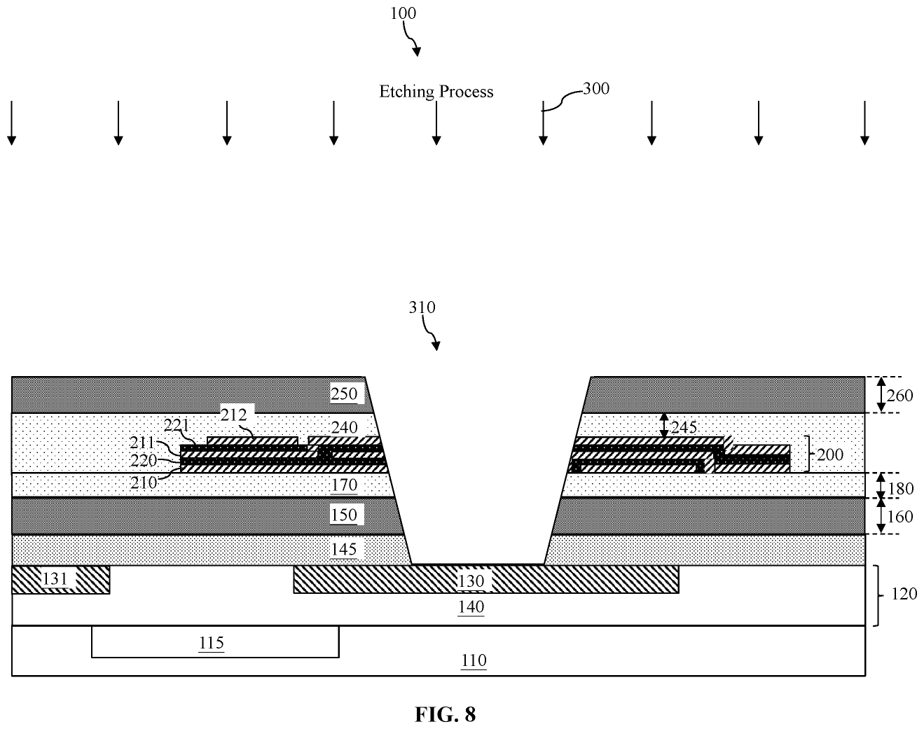

Referring now to FIG. 8, an etching process 300 is performed to the IC structure 100. In some embodiments, the etching process 300 may be performed by forming a patterned photoresist layer over the dielectric layer 250, and then etching (e.g., through a wet etching process or a dry etching process) the layers of the IC structure 100 below, while the patterned photoresist layer serves as an etching mask. The etching process 300 may stop once the metal line 130 is reached. Therefore, the etching process 300 etches an opening 310 that extends vertically through the dielectric layer 250, the dielectric layer 240, the MIM structure 200, the dielectric layer 170, the dielectric layer 150, and the dielectric layer 145. As a result, a portion of an upper surface of the metal line 130 is exposed by the opening 310.

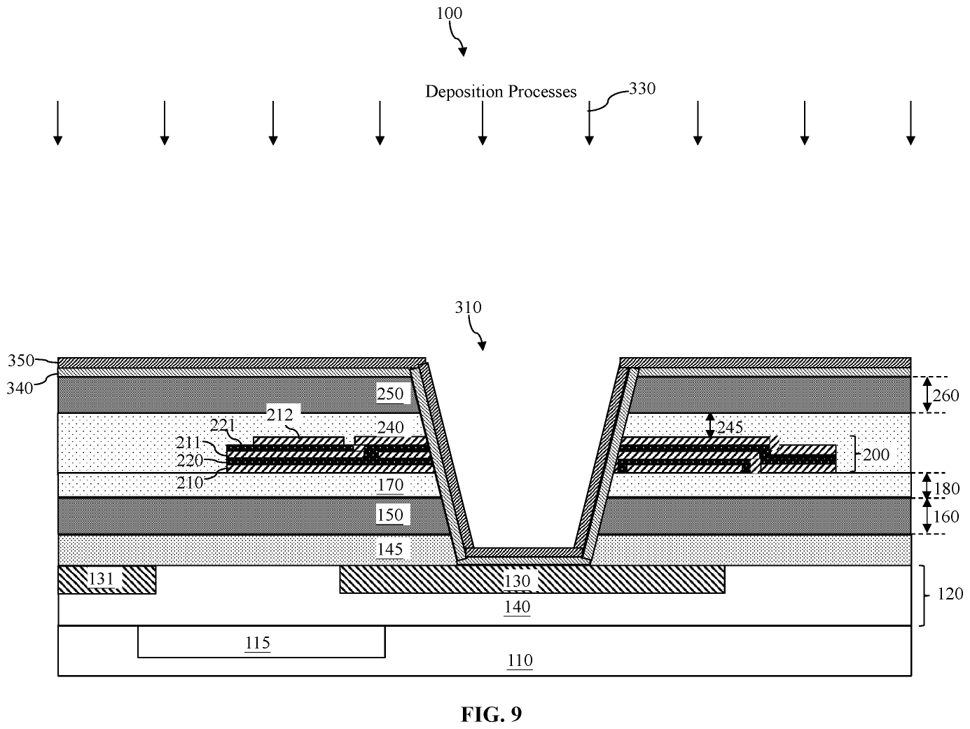

Referring now to FIG. 9, a plurality of deposition processes 330 are performed to the IC structure 100 form a barrier layer 340 and a seed layer 350. The barrier layer 340 and the seed layer 350 partially fill the opening 310. For example, a deposition process such as a CVD process, a PVD process, an ALD process, or combinations thereof, may be performed to deposit the barrier layer 340 on the upper surfaces of the dielectric layer 250 and the metal line 130, as well as on the side surfaces of the various layers that define the side surface of the opening 310. In some embodiments, the barrier layer 340 may contain titanium or tungsten. The barrier layer 340 may prevent undesirable diffusion between a conductive structure that will be formed to fill the opening 310 and the various layers outside the conductive structure. The seed layer 350 is formed on the barrier layer 340, for example using a sputtering process, a CVD process, a PVD process, or an ALD process. In some embodiments, the seed layer 350 contains copper.

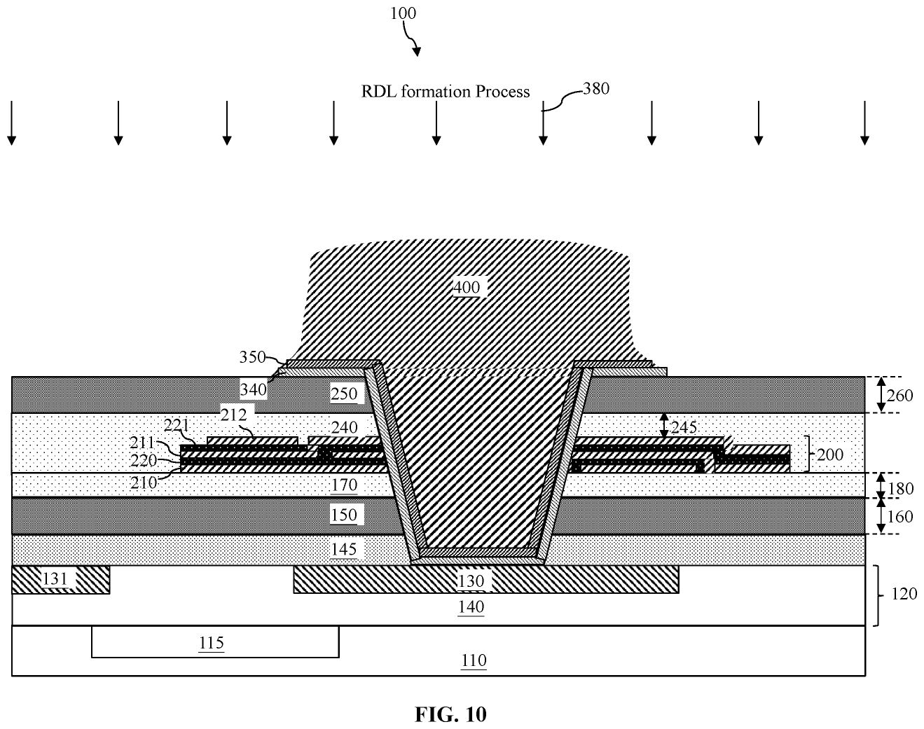

Referring now to FIG. 10, an RDL formation process 380 is performed to the IC structure 100 to form an RDL 400. In some embodiments, the RDL formation process 380 may include an electroplating process to form a bulk copper component over the seed layer 350, since the seed layer 350 also includes copper. In some embodiments, the RDL formation process 380 is configured such that the RDL 400 is formed to contain copper but not aluminum. The RDL formation process 380 may also include a lithography process to pattern the bulk copper component along with the seed layer 350 and the barrier layer 340 below. For example, a patterned photoresist layer may be formed, where the patterned photoresist layer may expose portions of the bulk copper component. One or more etching processes may then be performed to remove the exposed portions of the bulk copper component, as well as portions of the seed layer 350 and the barrier layer 340 located below the bulk copper component. The patterned photoresist layer serves as a protective mask to prevent the portions of the bulk copper component, the seed layer 350, and the barrier layer 340 therebelow from being etched away. The etching process may stop when the upper surface of the dielectric layer 250 is reached. The patterned photoresist layer may then be removed, for example using a photoresist ashing or stripping process. The remaining portion of the bulk copper component (which completely fills the opening 310, along with the portions of the seed layer 350 and the barrier layer 340 therebelow) may form the RDL 400.

Note that a portion of the RDL 400 protrudes vertically above the upper surface of the dielectric layer 250. In the cross-sectional side view of FIG. 10, the portion of the RDL 400 that protrudes vertically above the upper surface of the dielectric layer 250 has a trapezoid-like shape. For example, it is narrower at the top and wider at the bottom. However, the upper surface of this portion of the RDL 400 may be curved, or at least not flat. In addition, the side surfaces of this portion of the RDL 400 may be slanted, and at least the bottom segments of the side surfaces of this portion of the RDL 400 may be somewhat curved as well. The portion of the RDL 400 filling the opening 310 may have a substantially trapezoidal profile as well, though with a wider upper surface and a narrower bottom surface.

The RDL 400 is a copper RDL in the illustrated embodiment, and as a conductive structure, it provides electrical connectivity between the components of the interconnect structure 120 (e.g., the metal line 130) and other microelectronic components. It is understood that the RDL 400 may also be used to provide electrical connectivity to the various components of the MIM structure 200 in some embodiments, depending on the exact configuration and/or location of the RDL 400.

It is also understood that one or more additional layers may optionally be formed over the RDL 400 in some embodiments. For example, a dielectric layer (e.g., a silicon nitride layer) and/or a silicon oxide layer may be formed over the RDL 400. These additional layers may serve as protective layers for the RDL 400. For reasons of simplicity, these additional optional layers are not specifically illustrated herein.

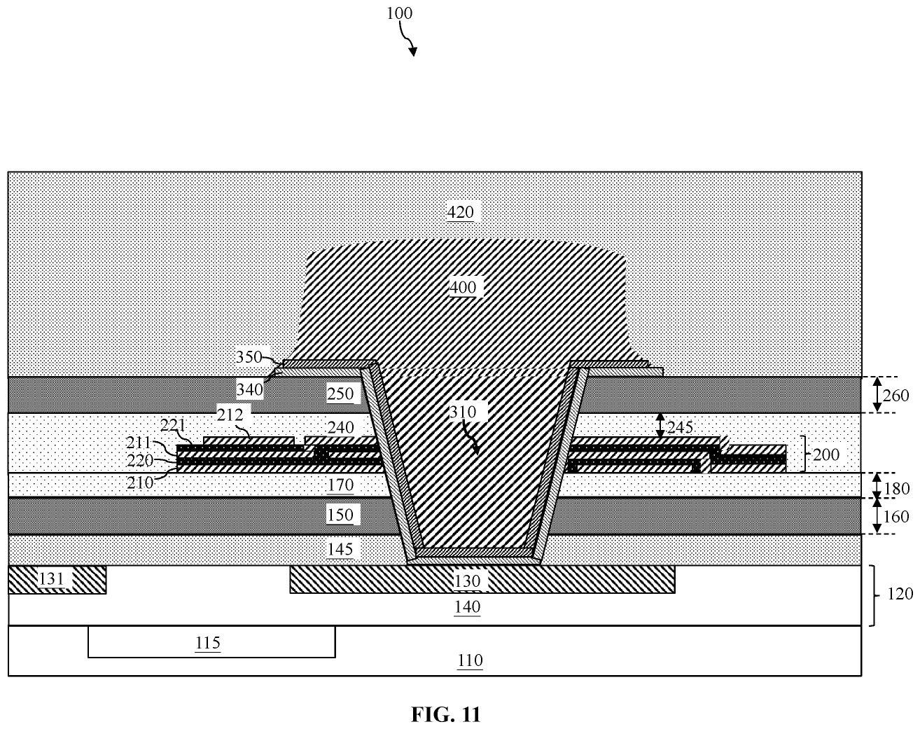

Referring now to FIG. 11, a dielectric layer 420 may be formed over the RDL 400 and over the upper surface of the dielectric layer 250. In some embodiments, the dielectric layer 145 may be formed using one or more deposition processes, such as CVD, PVD. ALD, HDPCVD, or combinations thereof. In some embodiments, the dielectric layer 420 is formed to include silicon oxide. A planarization process, such as a CMP process, may be performed to planarize the upper surface of the dielectric layer 420.

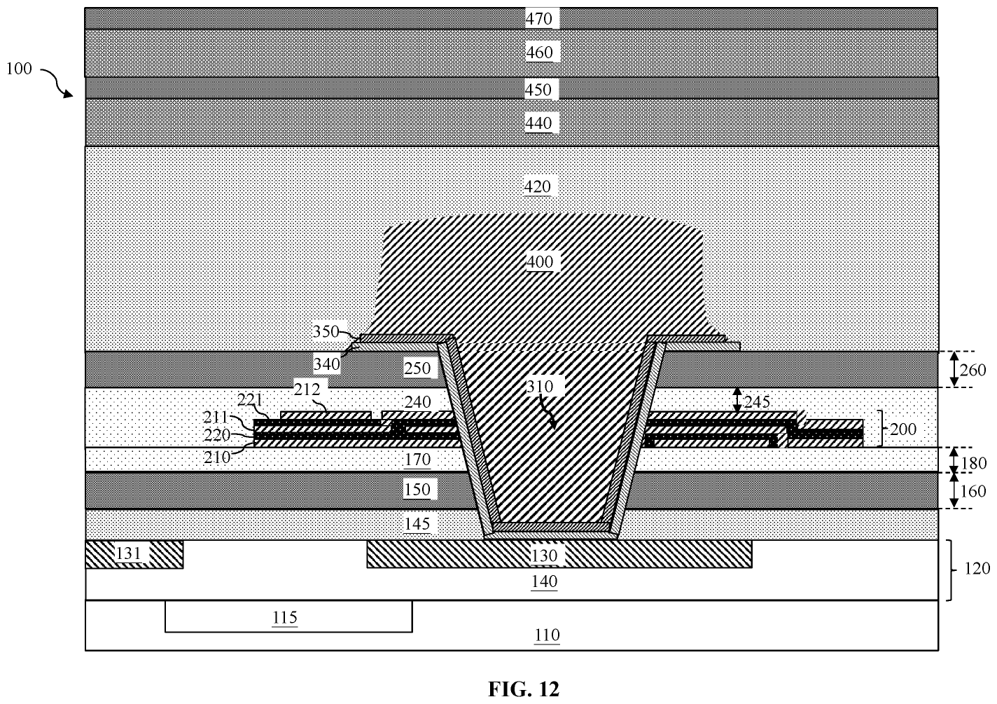

Referring now to FIG. 12, a plurality of deposition processes, such as CVD, PVD. ALD, or combinations thereof, may be performed to form a plurality of layers over the dielectric layer 420. For example, a Tetra Ethyl-Ortho-Silicate (TEOS) layer 440 is formed over the dielectric layer 420, an etching stop layer 450 is formed over the TEOS layer 440, another TEOS layer 460 is formed over the etching stop layer 450, and an anti-reflection layer 470 is formed over the TEOS layer 460. In some embodiments, the etching stop layer includes silicon nitride, and the anti-reflection layer includes silicon oxynitride. It is understood that a planarization process, such as a CMP process, may be performed to planarize the upper surface of each of the layers 440, 450, 460, and 470, following their respective depositions.

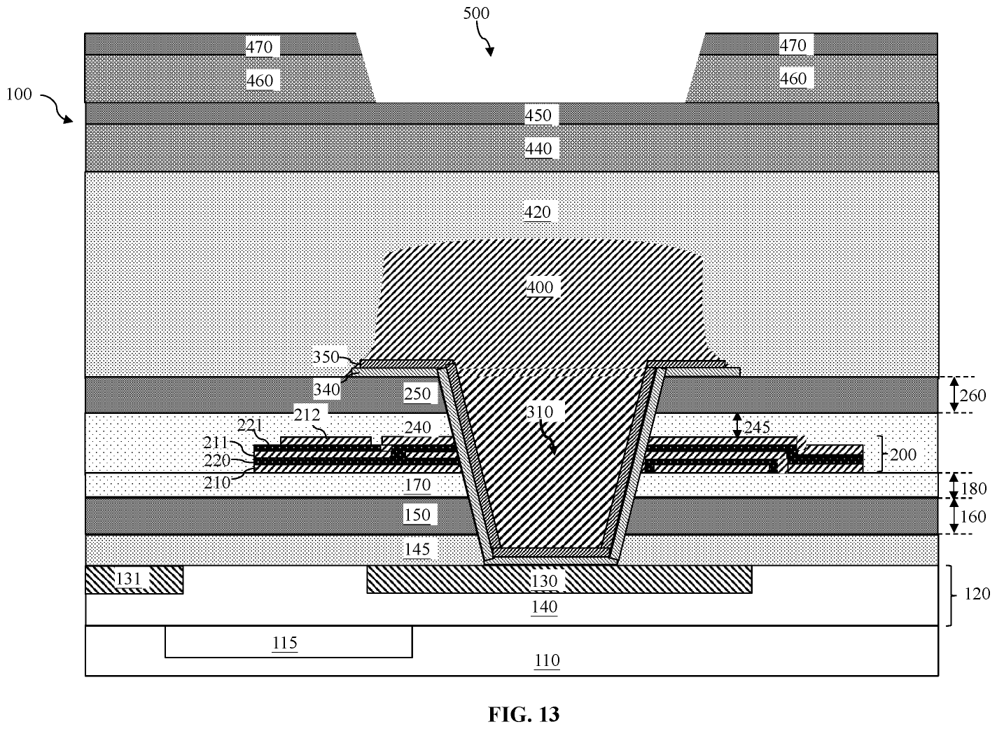

Referring now to FIG. 13, one or more etching processes may be performed to form an opening 500. The etching processes may include wet etching processes in some embodiments or dry etching processes in other embodiments. In some embodiments, a patterned photoresist layer is formed over the anti-reflection layer 470 before the etching processes are performed. The patterned photoresist layer may serve as an etching mask while the etching processes etch away portions of the anti-reflection layer 470 and the TEOS layer 460 exposed by the patterned photoresist layer. The etching processes may stop once the etching stop layer 450 is reached. In this manner, the opening 500 extends vertically through the anti-reflective layer 470 and the TEOS layer 460 and exposes a portion of an upper surface of the etching stop layer 450.

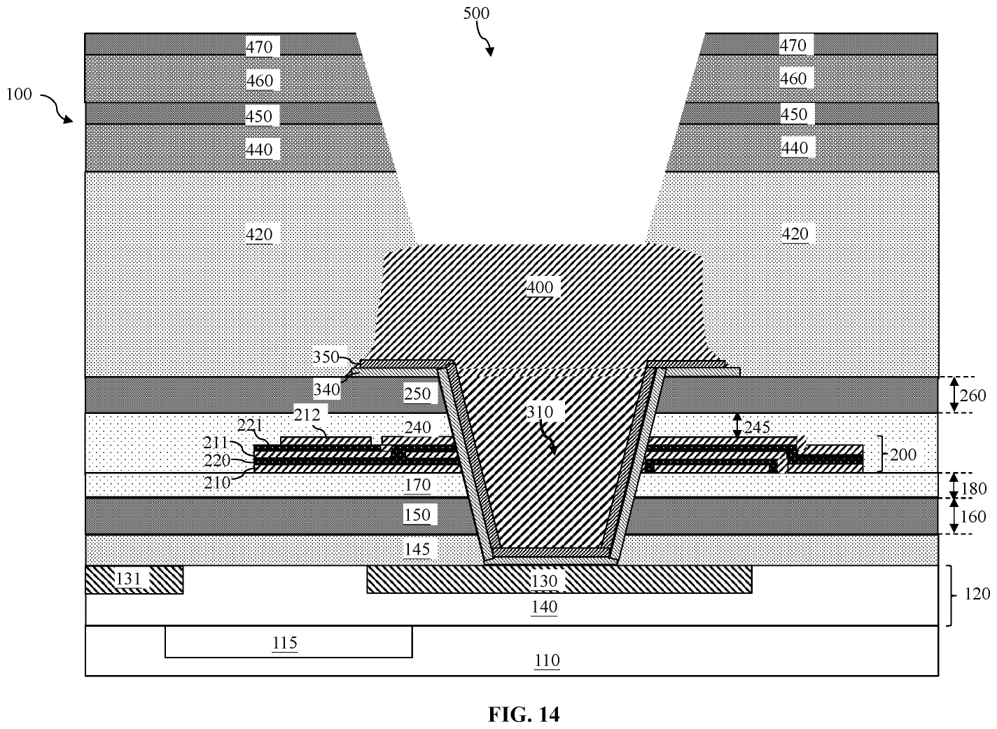

Referring now to FIG. 14, one or more etching processes may be performed to vertically extend the opening 500 further downward, such that the opening 500 extends vertically through the anti-reflective layer 470, the TEOS layer 460, the etching stop layer 450, the TEOS layer 440, and partially through the dielectric layer 420. The etching processes may include wet etching processes in some embodiments or dry etching processes in other embodiments. The etching processes may stop once the RDL 400 is reached.

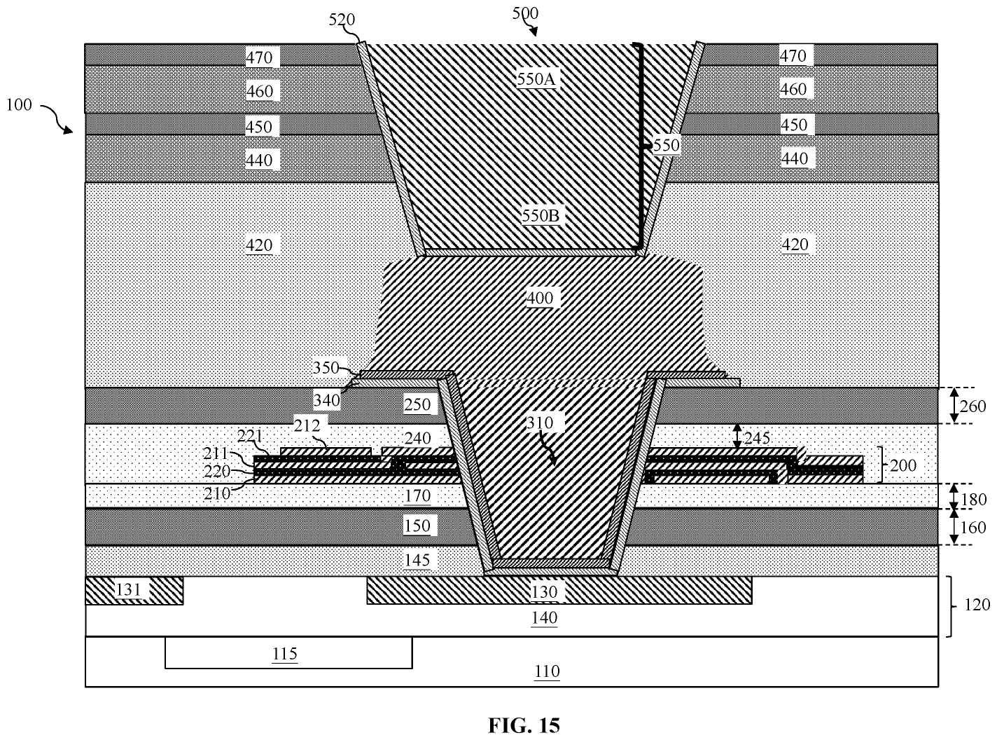

Referring now to FIG. 15, a barrier layer 520 is formed on the bottom surface and the side surfaces of the opening 500. In some embodiments, the barrier layer 520 may be formed by a deposition process such as CVD, PVD, ALD, or combinations thereof. In some embodiments, the barrier layer 520 may contain titanium or tungsten. The barrier layer 520 may prevent undesirable diffusion between the various layers and a conductive structure that will be formed to fill the opening 310.

A conductive structure 550 is also formed over the barrier layer 520 and fills the remainder of the opening 500. The conductive structure 550 may be formed using an electroplating process, which may involve forming a seed metal layer (e.g., a copper seed layer) on the barrier layer 520 and then forming the remainder of the conductive structure 550 on the seed metal layer. In some embodiments, an upper portion of the conductive structure 550 may be referred to as a bump pad metal 550A, and a lower portion of the conductive structure 550 may be referred to as a bump pad via 550B. In any case, the conductive structure 550 is electrically coupled to the RDL 400, and it may be used to gain electrical access to the rest of the IC structure 100. Furthermore, the conductive structure 550 may be used to connect to other conductive structures (e.g., other conductive bumps or conductive pads) that are external to the IC structure 100.

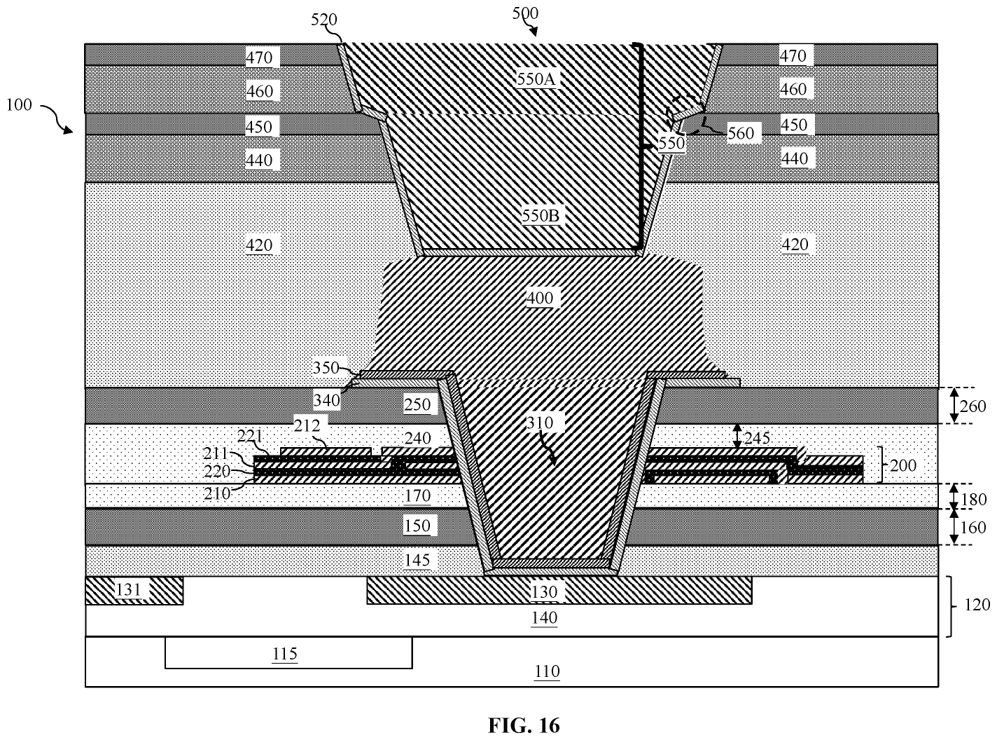

Note that although FIG. 15 illustrates the conductive structure 550 as having substantially linear sidewalls, this is not necessarily the case in other embodiments. For example, referring to an alternative embodiment illustrated in FIG. 16, the sidewalls of the conductive structure 550 may have distinct steps such as the step 560 (see the portion corresponding to the dashed circle in FIG. 16). Similarly, the barrier layer 520 is formed to have such a step 560 between the etching stop layer 450 and the TEOS layer 460 as well. In other words, the sidewalls of the bump pad metal 550A protrudes farther out laterally more so that the sidewalls of the bump pad via 550B. Such a step 560 may be a result of the fabrication processes used to etch the opening (through the layers 440-470) that is eventually filled by the conductive structure 550. For example, the portion of such an opening to be filled by the bump pad via 550B may be etched to be narrower than the portion of such an opening to be filled by the bump pad metal 550A.

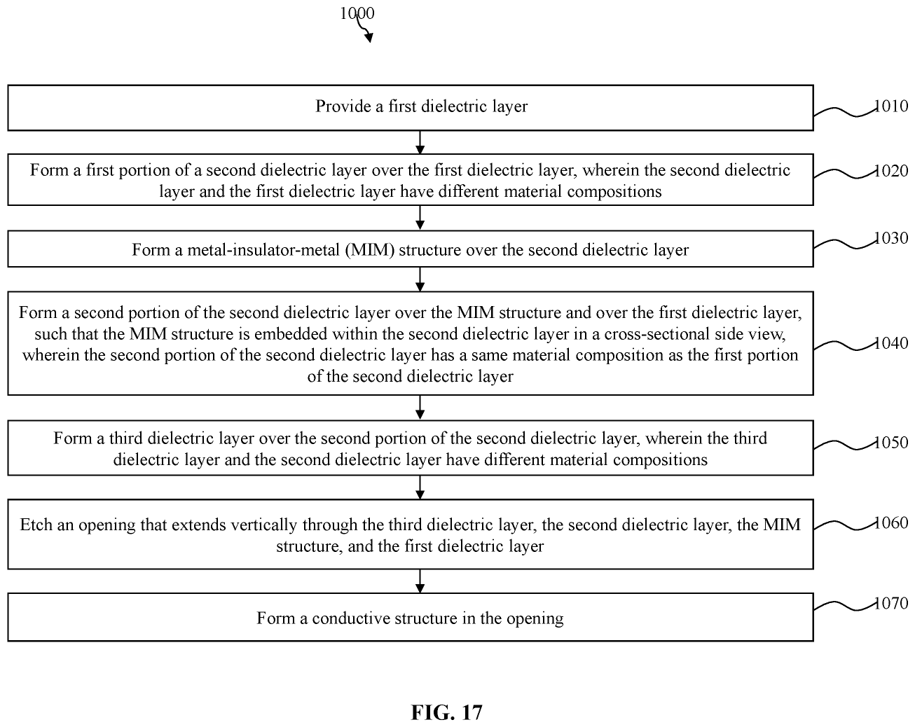

FIG. 17 is a flowchart illustrating a method 1000 according to an embodiment of the present disclosure. The method 1000 includes a step 1010 to provide a first dielectric layer. In some embodiments, a first silicon nitride (SiN) material is deposited as the first dielectric layer.

The method 1000 includes a step 1020 to form a first portion of a second dielectric layer over the first dielectric layer. The second dielectric layer and the first dielectric layer have different material compositions. In some embodiments, a silicon oxide (SiO₂) material is deposited as the first portion of the second dielectric layer.

The method 1000 includes a step 1030 to form a metal-insulator-metal (MIM) structure over the second dielectric layer. In some embodiments, the MIM structure is formed by depositing a first metal-containing layer over the second dielectric layer, depositing a first insulator layer over the first metal-containing layer, and depositing a second metal-containing layer over the first insulator layer. In some embodiments, the first metal-containing layer and the second metal-containing layer are deposited using titanium nitride (TiN). In some embodiments, the first insulator layer is deposited using hafnium zirconium oxide (HZO). In some embodiments, the forming of the MIM structure further comprises: depositing a second insulator layer over the second metal-containing layer, and depositing a third metal-containing layer over the second insulator layer.

The method 1000 includes a step 1040 to form a second portion of the second dielectric layer over the MIM structure and over the first dielectric layer, such that the MIM structure is embedded within the second dielectric layer in a cross-sectional side view. The second portion of the second dielectric layer has a same material composition as the first portion of the second dielectric layer. In some embodiments, a silicon oxide (SiO₂) material is deposited as the second portion of the second dielectric layer.

The method 1000 includes a step 1050 to form a third dielectric layer over the second portion of the second dielectric layer. The third dielectric layer and the second dielectric layer have different material compositions. In some embodiments, the third dielectric layer is formed by depositing a second silicon nitride (SiN) material as the third dielectric layer.

The method 1000 includes a step 1060 to etch an opening that extends vertically through the third dielectric layer, the second dielectric layer, the MIM structure, and the first dielectric layer.

The method 1000 includes a step 1070 to form a conductive structure in the opening. In some embodiments, the conductive structure is formed by a copper electroplating (ECP) process.

It is understood that additional processes may be performed before, during, or after the steps 1010-1070 of the method 1000. For example, the method 1000 may include the following steps: depositing a passivation layer over the conductive structure and over the third dielectric layer, etching a recess in the passivation layer, the recess exposing a portion of the conductive structure, and forming a conductive via in the recess. For reasons of simplicity, other additional steps are not discussed herein in detail.

In summary, the present disclosure involves an improved copper RDL formation scheme. According to the copper RDL formation scheme of the present disclosure, the MIM structure (e.g., the MIM structure 200) is embedded in an oxide-based material, for example, in dielectric layers 170 and 240 that contain silicon oxide (SiO₂). By doing so, the copper RDL scheme of the present disclosure offers advantages over conventional copper RDL schemes. It is understood, however, that other embodiments may offer additional advantages, and not all advantages are necessarily disclosed herein, and that no particular advantage is required for all embodiments. One advantage is improved reliability and/or defection reduction. In more detail, whereas existing copper RDL schemes form a metal-containing layer of the MIM structure on a nitride material, the present disclosure forms the metal-containing layer of the MIM structure directly on silicon oxide (e.g., the metal-containing layer 210 is formed directly on the dielectric layer 170, which contains silicon oxide). The formation of the metal-containing layer 210 on silicon oxide promotes the formation of a high quality metal-containing layer 210. The insulator layer 220 that is subsequently formed over the metal-containing layer 210 may also have a better crystal lattice structure in the present application compared to existing copper based RDL schemes. As a result, the insulator layer 220 may achieve a desired high dielectric constant and is less likely to break/fail. As such, failures such as TDDB may be reduced, and device performance and/or reliability may be improved. Other advantages include compatibility with existing fabrication and/or packaging processes, so the present disclosure does not require additional processing and is therefore easy and cheap to implement.

Thus, the present disclosure provides a device. The device includes a first dielectric layer. A second dielectric layer is disposed over the first dielectric layer. The second dielectric layer and the first dielectric layer have different material compositions. A metal-insulator-metal (MIM) structure is embedded in the second dielectric layer. A third dielectric layer is disposed over the second dielectric layer. The third dielectric layer and the second dielectric layer have different material compositions. The first dielectric layer or the third dielectric layer may contain silicon nitride (SiN), the second dielectric layer may contain silicon oxide (SiO₂).

The present disclosure also provides a structure. The structure includes a first silicon nitride layer. A silicon oxide layer is located over the first silicon nitride layer. A metal-insulator-metal (MIM) structure is embedded in the silicon oxide layer. The MIM structure includes a plurality of metal-containing layers and insulator layers. Each of the insulator layers is located between two adjacent ones of the metal-containing layers. A second silicon nitride layer is located over the silicon oxide layer. A conductive structure extends vertically through the second silicon nitride layer, the silicon oxide layer, the MIM structure, and the first silicon nitride layer in a cross-sectional side view. The conductive structure contains copper but not aluminum.

The present disclosure further provides a method. A first dielectric layer is provided. A first portion of a second dielectric layer is formed over the first dielectric layer. The second dielectric layer and the first dielectric layer have different material compositions. A metal-insulator-metal (MIM) structure is formed over the second dielectric layer. A second portion of the second dielectric layer is formed over the MIM structure and over the first dielectric layer, such that the MIM structure is embedded within the second dielectric layer in a cross-sectional side view. The second portion of the second dielectric layer has a same material composition as the first portion of the second dielectric layer. A third dielectric layer is formed over the second portion of the second dielectric layer. The third dielectric layer and the second dielectric layer have different material compositions. An opening is etched that extends vertically through the third dielectric layer, the second dielectric layer, the MIM structure, and the first dielectric layer. A conductive structure is formed in the opening.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
a first dielectric layer;
a second dielectric layer disposed over the first dielectric layer, wherein the second dielectric layer and the first dielectric layer have different material compositions;
a metal-insulator-metal (MIM) structure embedded in the second dielectric layer; and
a third dielectric layer disposed over the second dielectric layer, wherein the third dielectric layer and the second dielectric layer have different material compositions.

2. The device of claim 1, wherein:
the first dielectric layer or the third dielectric layer contains silicon nitride (SIN); and
the second dielectric layer contains silicon oxide (SiO₂).

3. The device of claim 1, wherein:
the MIM structure includes a plurality of metal-containing layers and a plurality of insulator layers; and
each of the insulator layers is sandwiched between two respective metal-containing layers.

4. The device of claim 3, wherein:
each of the metal-containing layers includes a titanium nitride (TiN) layer; and
each of the insulator layers includes a hafnium zirconium oxide (H2O) layer.

5. The device of claim 1, further comprising a conductive structure that extends vertically through the first dielectric layer, the second dielectric layer, and the third dielectric layer.

6. The device of claim 5, wherein the conductive structure extends vertically through the MIM structure.

7. The device of claim 5, wherein the conductive structure contains copper but not aluminum.

8. The device of claim 5, further comprising:
a fourth dielectric layer disposed below the first dielectric layer; and
a metal component embedded in the fourth dielectric layer, wherein the conductive structure is disposed on, and electrically coupled to, the metal component.

9. The device of claim 8, further comprising a fifth dielectric layer disposed between the first dielectric layer and the fourth dielectric layer, wherein the fifth dielectric layer and the first dielectric layer have different material compositions.

10. The device of claim 9, wherein:
the first dielectric layer contains silicon nitride (SiN);
the fifth dielectric layer contains silicon carbon nitride (SiCN); and
the conductive structure extends vertically through the fifth dielectric layer.

11. A structure, comprising:
a first silicon nitride layer;
a silicon oxide layer located over the first silicon nitride layer;
a metal-insulator-metal (MIM) structure embedded in the silicon oxide layer, wherein the MIM structure includes a plurality of metal-containing layers and insulator layers, and wherein each of the insulator layers is located between two adjacent ones of the metal-containing layers;
a second silicon nitride layer located over the silicon oxide layer; and
a conductive structure that extends vertically through the second silicon nitride layer, the silicon oxide layer, the MIM structure, and the first silicon nitride layer in a cross-sectional side view, wherein the conductive structure contains copper but not aluminum.

12. The structure of claim 11, further comprising:
a dielectric layer located below the first silicon nitride layer;
a metal component embedded in the dielectric layer;
a silicon carbon nitride layer located between the dielectric layer and the first silicon nitride layer, wherein the conductive structure extends vertically through the silicon carbon nitride layer and is electrically coupled to the metal component that is embedded in the dielectric layer; and
a passivation layer located over the second silicon nitride layer, wherein the conductive structure extends at least partially through the passivation layer in the cross-sectional side view.

13. The structure of claim 11, wherein:
each of the metal-containing layers of the MIM structure includes a titanium nitride (TiN) layer; and
each of the insulator layers of the MIM structure includes a hafnium zirconium oxide (HZO) layer.

14. A method, comprising:
providing a first dielectric layer;
forming a first portion of a second dielectric layer over the first dielectric layer, wherein the second dielectric layer and the first dielectric layer have different material compositions;
forming a metal-insulator-metal (MIM) structure over the second dielectric layer;
forming a second portion of the second dielectric layer over the MIM structure and over the first dielectric layer, such that the MIM structure is embedded within the second dielectric layer in a cross-sectional side view, wherein the second portion of the second dielectric layer has a same material composition as the first portion of the second dielectric layer;
forming a third dielectric layer over the second portion of the second dielectric layer, wherein the third dielectric layer and the second dielectric layer have different material compositions;
etching an opening that extends vertically through the third dielectric layer, the second dielectric layer, the MIM structure, and the first dielectric layer; and
forming a conductive structure in the opening.

15. The method of claim 14, wherein:
the providing the first dielectric layer comprises depositing a first silicon nitride (SiN) material as the first dielectric layer;
the forming the first portion of the second dielectric layer and the forming the second portion of the second dielectric layer each comprise depositing a silicon oxide (SiO₂) layer as the first portion and the second portion of the second dielectric layer; and
the forming the third dielectric layer comprises depositing a second silicon nitride (SiN) material as the third dielectric layer.

16. The method of claim 14, wherein the forming the MIM structure comprises:
depositing a first metal-containing layer over the second dielectric layer;
depositing a first insulator layer over the first metal-containing layer; and
depositing a second metal-containing layer over the first insulator layer.

17. The method of claim 16, wherein:
the first metal-containing layer and the second metal-containing layer are deposited using titanium nitride (TiN); and
the first insulator layer is deposited using hafnium zirconium oxide (HZO).

18. The method of claim 16, wherein the forming the MIM structure further comprises:
depositing a second insulator layer over the second metal-containing layer; and
depositing a third metal-containing layer over the second insulator layer.

19. The method of claim 14, wherein the conductive structure is formed by a copper electroplating (ECP) process, and wherein a portion of the conductive structure protrudes vertically above the third dielectric layer in the cross-sectional side view.

20. The method of claim 19, further comprising:
depositing a passivation layer over the conductive structure and over the third dielectric layer;
etching an opening in the passivation layer, the opening exposing a portion of the conductive structure; and
forming a conductive via in the opening.
